(19) United States
(12) Patent Application Publication
(10) Pub. No.: US 2017/0016116 A1
(43) Pub. Date: Jan. 19, 2017

(54) GRAPHENE PRODUCTION METHOD, GRAPHENE PRODUCTION APPARATUS AND GRAPHENE PRODUCTION SYSTEM

(71) Applicant: TOKYO ELECTRON LIMITED, Tokyo (JP)

(72) Inventors: Daisuke NISHIDE, Nirasaki City (JP); Takashi MATSUMOTO, Nirasaki City (JP); Ryota IFUKU, Nirasaki City (JP)

(21) Appl. No.: 15/202,869

(22) Filed: Jul. 6, 2016

(30) Foreign Application Priority Data
Jul. 16, 2015 (JP) 2015-142460

(51) Int. Cl. C23C 16/455; C01B 31/04

(52) U.S. Cl. CPC C23C 16/45544; C01B 31/0453

(57) ABSTRACT

There is provided a graphene production method including: forming a catalyst metal film on a surface of a substrate; heating the catalyst metal film; and cooling the heated catalyst metal film, wherein the forming a catalyst metal film includes introducing carbons into the catalyst metal film.

### CROSS-REFERENCE TO RELATED APPLICATION

This application claims the benefit of Japanese Patent Application No. 2015-142460, filed on Jul. 16, 2015, in the Japan Patent Office, the disclosure of Which is incorporated herein in its entirety by reference.

### TECHNICAL FIELD

The present disclosure relates to a graphene production method, a graphene production apparatus and a graphene production system.

### BACKGROUND

Graphene, which is a carbon atom aggregate of six-membered ring structure, has a high speed mobility, for example, 200,000 cm²/Vs, as compared with silicon (Si). As such, grapheme is under consideration as a material to be applied to semiconductor devices, for example, a ultrahigh speed switching device or a high frequency device. In addition, since graphene exhibits ballistic conductivity, graphene is under consideration as a wiring material substituted for copper (Cu) in semiconductor devices.

Graphene is produced using a catalyst metal film as a base film. Specifically, graphene is produced by: activating a nickel (Ni) film constituting the catalyst metal film by heating; dissolving carbons from a carbon atom-containing gas into the activated nickel film; diffusing the carbons into the nickel film; cooling down the nickel film to reduce solubility of the carbons; and crystallizing and precipitating the carbons. For this reason, quality of the nickel film closely involves quality of graphene.

In particular, the present inventors suggested that, since a surface state (e.g., flatness) of the nickel film closely involves the quality of graphene, there is a need to preliminarily heat the nickel film in order to prevent gas evaporated from impurities contained in the nickel film from being confined inside the nickel film.

However, when dissolving and diffusing carbons from the carbon atom-containing gas into the activated nickel film, some portions into which the gas is likely to be introduced and other portions into which the gas is unlikely to be introduced are generated in the surface of the nickel film. This causes a fluctuation in introduction amount of the carbons into the nickel film, so that the carbons are unevenly diffused inside the nickel film. In this case, density of graphene precipitated in the surface of the nickel film also becomes uneven. This makes it difficult to produce a high quality of graphene.

### SUMMARY

Some embodiments of the present disclosure provide a graphene production method, a graphene production apparatus and a graphene production system, which are capable of producing high quality of graphene.

According to one embodiment of the present disclosure, there is provided a graphene production method including: forming a catalyst metal film on a surface of a substrate; heating the catalyst metal film; and cooling the heated catalyst metal film, wherein the forming a catalyst metal film includes introducing carbons into the catalyst metal film.

According to another embodiment of the present disclosure, there is provided a graphene production apparatus which forms a catalyst metal film on a surface of a substrate, heats the catalyst metal film, and cools down the heated catalyst metal film, wherein when forming the catalyst metal film, carbons are introduced into the catalyst metal film.

According to yet another embodiment of the present disclosure, there is provided a graphene production system provided with a plurality of processing chambers, wherein at least two of the plurality of processing chambers are configured as a metal film formation chamber for forming a catalyst metal film on a surface of a substrate and a graphene precipitation chamber for precipitating graphene in a surface of the catalyst metal film, wherein the metal film formation chamber is configured to allow carbons to be introduced into the catalyst metal film, when forming the catalyst metal film, wherein the graphene precipitation chamber is configured to heat the formed catalyst metal film and to cool down the heated catalyst metal film.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIGS. 1A to 1C are partial cross-sectional views schematically showing test pieces used in a preceding experiment performed by the present inventors, FIGS. 1A and 1B showing test pieces each having a PVD nickel film, and FIG. 1C showing a test piece having a CVD nickel film.

FIGS. 2A to 2C are graphs showing Raman spectra of diffused light obtained from a surface of graphene precipitated in the test pieces of FIGS. 1A to 1C, respectively, FIG. 2A showing a Raman spectrum for the test piece of FIG. 1A, FIG. 2B showing a Raman spectrum for the test piece of FIG. 1B, and FIG. 2C showing a Raman spectrum for the test piece of FIG. 1C.

FIG. 3 is graphs showing results of SIMS of the test pieces of FIGS. 1A to 1C.

FIG. 4 is a schematic plan view showing a graphene production system according to a first embodiment of the present disclosure.

FIGS. 5A to 5D are process views explaining the graphene production method according to the first embodiment of the present disclosure.

FIGS. 6A to 6D are process views explaining a graphene production method according to a second embodiment of the present disclosure.

FIGS. 7A to 7D are process views explaining a graphene production method according to a third embodiment of the present disclosure.

FIGS. 8A to 8D are process views showing a first modification of the graphene production method according to the third embodiment of the present disclosure.

FIGS. 9A to 9B are process views showing a second modification of the graphene production method according to the third embodiment of the present disclosure.

FIGS. 10A to 10D are process views showing a modification in which the graphene production methods according to the second and third embodiments of the present disclosure are combined.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure ay be practiced without these specific details. In other instances, well-known methods, procedures, systems, and components have not been described in detail so as not to unnecessarily obscure aspects of the various embodiments.

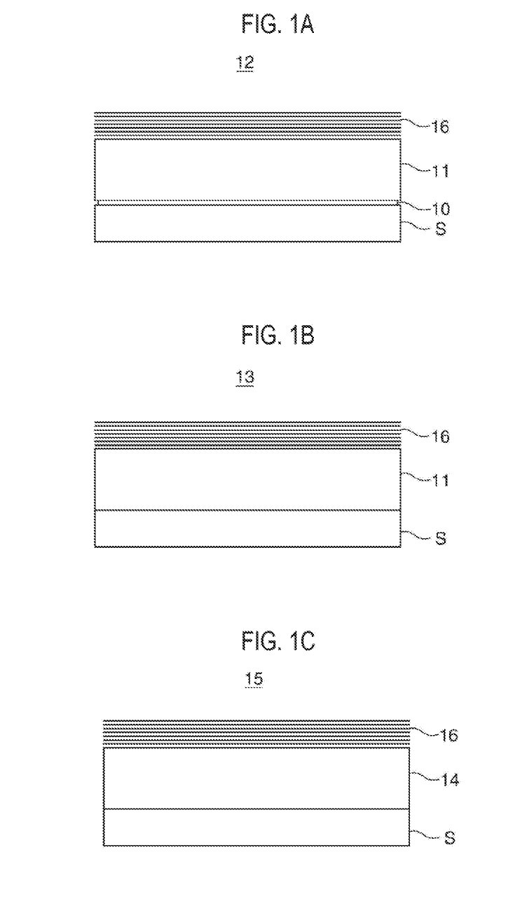

First, prior to the present disclosure, the present inventors carried out some experiments to check an influence of a difference between production methods of a catalyst metal film on quality of precipitated graphene. To this end, three kinds of test pieces, that is to say, a test piece 12 (FIG. 1A) that includes a substrate S composed of a silicon dioxide (SiO₂), a titanium nitride (TiN) film 10 formed as an adhesion layer on a surface of the substrate S, and a PVD nickel film 11 formed as a catalyst metal film on the titanium nitride film 10; a test piece 13 (FIG. 1B) that includes a substrate S and a PVD nickel film 11 formed on a surface of the substrate S, and a test piece 15 (FIG. 1C) that includes a substrate S and a CVD nickel film 14 formed as a catalyst metal film on a surface of the substrate S, were prepared. These test pieces 12, 13 and 15 were activated by heating. Subsequently, carbons from a raw material gas containing carbon atoms were dissolved in each of the test pieces 12, 13 and 15. Further, each of the test pieces 12, 13 and 15 was cooled down to precipitate a graphene 16. The PVD nickel film 11 is formed by PVD using nickel as a target material, and the CVD nickel film 14 is formed by CVD using a nickel compound gas.

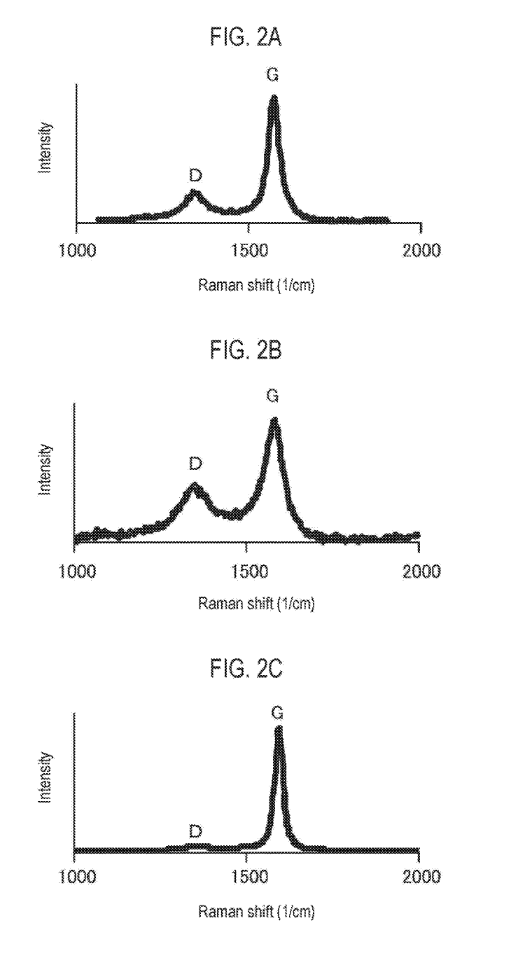

Thereafter, Raman spectra of diffused light obtained from the surface of the graphene 16 precipitated in each of the test pieces 12, 13, 15 were detected to calculate a G/D ratio in each of the Raman spectra. The G/D ratio is an index representing quality of the respective graphene and refers to a ratio of a G band (a peak caused by in-plane oscillation of graphene) to a D band (a peak caused by a defect structure in graphene) in the Raman spectrum. A higher G/D ratio indicates better quality graphene. The test piece 12 had a G/D ratio of about 4 (see FIG. 2A) and the test piece 13 had a G/D ratio of about 2 (see FIG. 2B). On the other hand, the test piece 15 had a G/D ratio of about 30 (see FIG. 2C). In other words, it was confirmed that the graphene 16 of the test piece 15 had better quality than others.

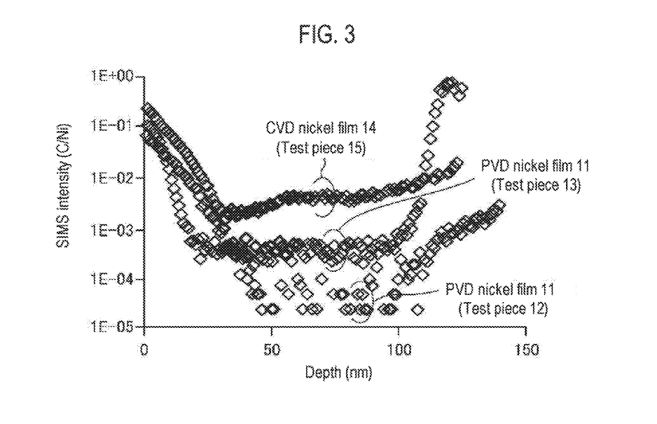

In this regard, the present inventors measured a concentration of carbon with respect to nickel the PVD nickel film 11 or the CVD nickel film 14 in each of the test pieces 12, 13, 15 by a secondary ion mass spectrometry (SIMS) in order to find out the reason for the high quality of the graphene 16 of the test piece 15. As a result, as shown in FIG. 3, the present inventors found that a small amount of carbons is included in both the PVD nickel film 11 and the CVD nickel film 14. In particular, the present inventors found that the concentration of carbons with respect to nickels in the CVD nickel film 14 of the test piece 15 is higher than that in the PVD nickel film 11 of each of the test pieces 12 and 13, and that the concentration of carbons with respect to nickels in the CVD nickel film 14 is uniformly distributed in a depth direction thereof without having substantial fluctuation.

From the above results, the present inventors found that, in order to obtain a high quality of graphene, the catalyst metal film needs to have a high carbon concentration and the carbon concentration needs to be evenly distributed in the depth direction, that is to say, carbon atoms need to be evenly diffused in the catalyst metal film, The present disclosure is based on this finding.

Hereinafter, embodiments of the present disclosure will be described in detail with reference to the accompanying drawings.

First, a first embodiment of the present disclosure will be described.

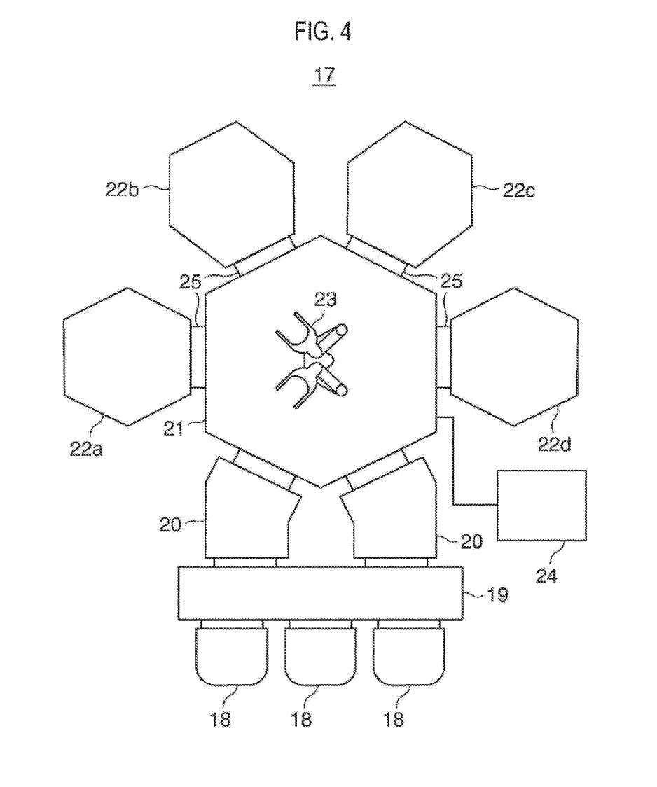

FIG. 4 is a schematic plan view showing a graphene production system according to a first embodiment of the present disclosure. For the sake of easier understanding, FIG. 4 is shown such that some internal configurations of a graphene production system 17 are revealed.

Referring to FIG. 4, the graphene production system 17 is provided with three load ports 18 each of which is installed to be connected with a hoop (not shown) for receiving a predetermined sheet of substrates, for example, semiconductor wafers (hereinafter, simply referred to as “wafers”). Further, the graphene production system 17 includes a loader chamber 19 which is placed adjacent to the load ports 18 and is configured to load/unload the wafers into/from the hoop. The loader chamber 19 is provided with a transfer robot (not shown) installed therein and configured to transfer the wafers.

Further, two load lock chambers 20 used as substrate transfer chambers are disposed at a side facing the load ports 18 in the loader chamber 19 with the loader chamber 19 interposed between the load lock chambers 20 and the load ports 18. The loader chamber 19 serves to transfer the wafers between the hoops connected to the load ports 18 and the load lock chambers 20, while each of the load lock chambers 20 acts as an intermediate transfer chamber for transferring the wafers between the loader chamber 19 and a substrate transfer chamber 21 (to be described later).

The substrate transfer chamber 21 has, for example, a hexagonal shape when viewed from the top, and is placed at sides facing the loader chamber 19 in the load lock chambers 20 with the load lock chambers 20 interposed between the loader chamber 19 and the substrate transfer chamber 21, Four processing chambers 22a to 22d are radially arranged around the substrate transfer chamber 21 while being connected to the substrate transfer chamber 21. The substrate transfer chamber 21 includes a transfer robot 23 installed therein and is configured to transfer the wafers. The transfer robot 23 transfers the wafers between the respective processing chambers 22a to 22d and the respective load lock chambers 20.

Further, the graphene production system 17 includes a controller 24 configured to control operations of respective components of the graphene production system 17, The controller 24 includes a central processing unit (CPU) and memories. The CPU executes a graphene production method (to be described below) in accordance with a program stored in the memories.

In the graphene production system 17, each of the processing chambers 22a to 22d is coupled to the substrate transfer chamber 21 through a respective gate valve 25. The gate valves 25 control communication between the respective processing chambers 22a to 22d and the substrate transfer chamber 21. In this embodiment, the processing chamber (metal film formation chamber) 22a is to form a carbon-containing catalyst metal film 26 (to be described below), and the processing chamber (grapheme precipitation chamber) 22b is to precipitate a graphene 27 (to be described below in the wafer on which the carbon-containing catalyst metal film 26 is formed.

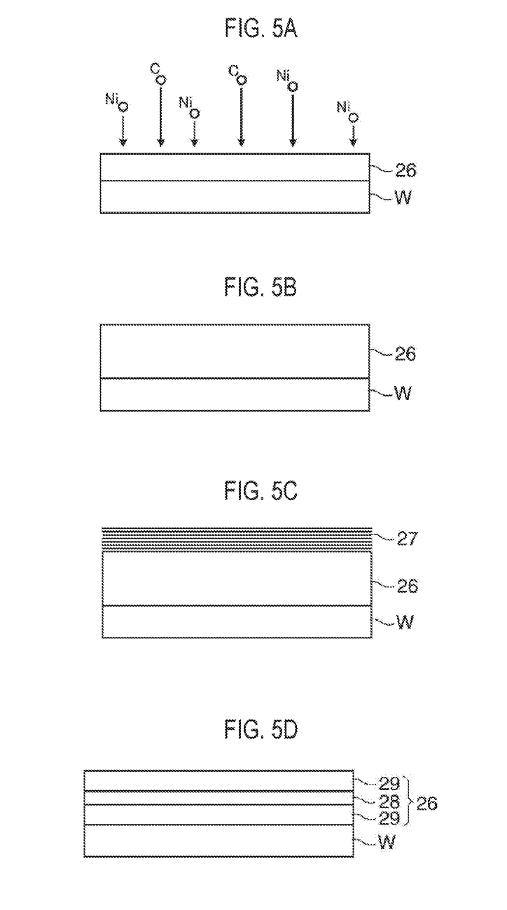

FIGS. 5A to 5D are process views explaining the graphene production method according to the first embodiment of the present disclosure.

First, in the processing chamber 22a, the carbon-containing catalyst metal film 26 is formed on a surface of the wafer W. Specifically, a metal film having a relatively high carbon solubility, for example, a nickel film, is formed by introducing carbons into the metal film. Thus, the carbon-containing catalyst metal film 26 is formed. An example of a method of forming the carbon-containing catalyst metal film 26 may include a PVD (FIG. 5A) using nickel and carbon as targets, a PVD using a nickel carbide as a target, a PVD using nickel as a target under a hydrocarbon gas atmosphere, or a CVD or ALD using gas of an organic nickel compound. In forming the carbon-containing catalyst metal film 26, forming a nickel film and supplying carbon into the nickel film are simultaneously performed. Thus, carbons are substantially evenly dispersed inside the carbon-containing catalyst metal film 26. In addition, the formed carbon-containing catalyst metal film 26 is composed of the nickel carbide, a mixture of nickel and carbon, or the organic nickel compound. A small amount of carbons is precipitated in a crystal grain boundary of nickel in the mixture of nickel and carbon.

Subsequently, in the processing chamber 22b, the carbon-containing catalyst metal film 26 is heated to diffuse carbons included in the carbon-containing catalyst metal film 26 (FIG. 5B) At this time, a carbon-containing gas, for example, an ethylene (C₂H₄) gas or an acetylene (C₂H₂) gas may be supplied toward the carbon-containing catalyst metal film 26. In other embodiments, when heating the carbon-containing catalyst metal film 26, the interior of the processing chamber 22b may be vacuum-exhausted or may be filled with an inert gas.

Thereafter, in the processing chamber 22b, the heated carbon-containing catalyst metal film 26 is cooled down. At this time, since solubility of carbons in the carbon-containing catalyst metal film 26 is lowered, saturated carbons are crystallized on the surface of the carbon-containing catalyst metal film 26, thereby precipitating the graphene 27 (FIG. 5C).

According to the graphene production method of FIGS. 5A to 5D, when forming the carbon-containing catalyst metal film 26, carbons are introduced into the nickel film constituting the carbon-containing catalyst metal film 26. That is to say, the formation of the nickel film and the introduction of carbons into the nickel film are simultaneously performed. Thus, there is no need to dissolve carbons from the carbon-containing gas into the catalyst metal film as in the related art. This makes it possible to suppress a fluctuation in introduction amount of carbons into the carbon-containing catalyst metal film 26, thus enabling carbons to be substantially evenly dispersed inside the carbon-containing catalyst metal film 26. Furthermore, since the carbons are substantially evenly dispersed, the carbons can be evenly diffused by heating the carbon-containing catalyst metal film 26. As a result, it is possible to produce the graphene 27 with high quality.

Furthermore, in the graphene production method of FIGS. 5A to 5D, since the carbon-containing catalyst metal film 26 is composed of the nickel carbide or the organic nickel compound, nickel atoms and carbon atoms are coupled to each other in each of the molecules constituting the carbon-containing catalyst metal film 26. In this operation, each molecule is evenly present in the carbon-containing catalyst metal film 26. It is therefore possible to reliably diffuse the carbon atoms in the carbon-containing catalyst metal film 26.

In the graphene production method of FIGS. 5A to 5D, the carbon-containing catalyst metal film 26 is formed by CVD, PVD or ALD. In other words, since there is no need to use a particular method in forming the carbon-containing catalyst metal film 26, the carbon-containing catalyst metal film 26 can be easily formed.

Furthermore, in the graphene production method of FIGS. 5A to 5D, the carbon-containing gas is supplied toward the carbon-containing catalyst metal film 26 in the course of heating the carbon-containing catalyst metal film 26, so that the carbons are dissolved in the carbon-containing catalyst metal film 26, thereby further increasing a concentration of the carbons. As a result, through the cooling down of the carbon-containing catalyst metal film 26, it is possible to easily precipitate the graphene 27 and control the number of layers of the precipitated graphene 27 by adjusting the concentration of the carbons.

Although in the aforementioned graphene production method of FIGS. 5A to 5D, the carbons have been described to be introduced into the nickel film in forming the nickel film, the method of forming the carbon-containing catalyst metal film 26 is not limited thereto. As an example, as shown in FIG. 5D, the graphene production method may include forming a pair of nickel films 29 on the surface of the wafer W with a solid carbon film 28 interposed between the pair of nickel films 29, heating the pair of nickel films 29 and the solid carbon film 28 to dissolve carbons from the solid carbon film 28 into the nickel films 29, and forming the carbon-containing catalyst metal film 26. Even in this case, since there is no need to dissolve carbons from the carbon-containing gas into each of the nickel films 29, it is possible to suppress fluctuation in the introduction amount of carbons into the carbon-containing catalyst metal film 26.

In addition, although in the aforementioned graphene production method of FIGS. 5A to 5D, nickel has been described to be used as a metal constituting the carbon-containing catalyst metal film 26, cobalt (Co), iron (Fe), titanium (Ti), rhodium (Rh), palladium (Pd), platinum (Pt), or mixtures of these metals, instead of nickel, may be used as the metal constituting the carbon-containing catalyst metal film 26.

Next, a second embodiment of the present disclosure will be described.

This embodiment is essentially identical in configuration and operation with the first embodiment described above, and a duplicate description thereof will be omitted. Only the differing configurations and operations will be described below

In this embodiment, the processing chamber (base film formation chamber) 22c is to form a high crystalline base film 30 (to be described below) and is provided with a heating mechanism (not shown), In this embodiment, the high crystalline base film 30 will be illustrated as being composed of a nickel film.

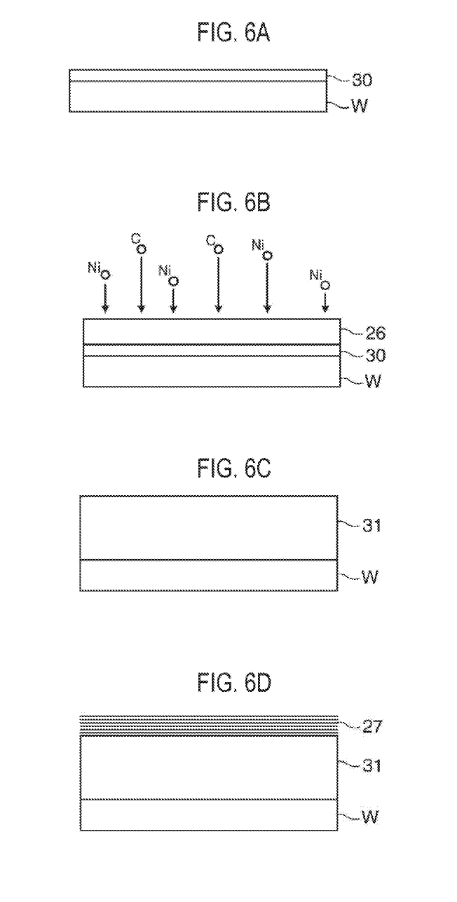

FIGS. 6A to 6D are process views explaining a graphene production method according to the second embodiment of the present disclosure.

First, in the processing chamber 22c, the high crystalline base film 30 is formed on a surface of the wafer W (FIG. 6A). Specifically, a film of nickels is formed on the surface of the wafer W by PVD using nickel as a target, and subsequently, the interior of the processing chamber 22c is filled with a hydrogen (H₂) gas. The nickel film is subjected to a heat treatment under a hydrogen gas atmosphere. This improves crystallinity of nickels in the high crystalline base film 30.

Subsequently, in the processing chamber 22a, a carbon-containing catalyst metal film 26 is formed to be brought into contact with the high crystalline base film 30 by, e.g., PVD using nickel and carbon as targets (FIG. 6B). At this time, crystallinity of the high crystalline base film 30 is imparted to the carbon-containing catalyst metal film 26. Accordingly, the carbon-containing catalyst metal film 26 also has high crystallinity.

Subsequently, in the processing chamber 22b, a graphene precipitation layer 31 is formed by dissolving the high crystalline base film 30 and the carbon-containing catalyst metal film 26 with respect to each other by heating (FIG. 6C). At this time, carbons contained in the carbon-containing catalyst metal film 26 are diffused into the graphene precipitation layer 31. In addition, since both the high crystalline base film 30 and the carbon-containing catalyst metal film 26 have high crystallinity, the graphene precipitation layer 31 also has high crystallinity. Furthermore, as in the first embodiment, when heating the high crystalline base film 30 and the carbon-containing catalyst metal film 26, the carbon-containing gas may be supplied toward the carbon-containing catalyst metal film 26. In other embodiments, when heating the high crystalline base film 30 and the carbon-containing catalyst metal film 26, the interior of the processing chamber 22b may be vacuum-exhausted or may be filled with an inert gas.

Thereafter, in the processing chamber 22b, the graphene precipitation layer 31 is cooled down. At this time, since solubility of the carbons in the graphene precipitation layer 31 is lowered, saturated carbons are crystallized in a surface of the graphene precipitation layer 31 to precipitate the graphene 27 (FIG. 6D).

According to the graphene production method of FIGS. 6A to 6D, since the high crystalline base film 30 is formed and subsequently the carbon-containing catalyst metal film 26 is formed to be brought into contact with the high crystalline base film 30, the high crystallinity of the high crystalline base film 30 is imparted to the carbon-containing catalyst metal film 26. Particularly, since both the carbon-containing catalyst metal film 26 and the high crystalline base film 30 are composed of nickel, the high crystallinity of the high crystalline base film 30 is surely imparted to the carbon-containing catalyst metal film 26. As a result, the graphene precipitation layer 31 formed by dissolving the high crystalline base film 30 and the carbon-containing catalyst metal film 26 can have high crystallinity. On the other hand, in general, since crystallinity of graphene precipitated from a catalyst metal film is significantly influenced. by crystallinity of the respective catalyst metal film, the high crystallinity of graphene is increased with an increase in high crystallinity of the catalyst metal film. Thus, according the graphene production method of FIGS. 6A to 6D, it is possible to produce the graphene 27 haying further improved crystallinity from the graphene precipitation layer 31 having high crystallinity.

Furthermore, in the graphene production method of FIGS. 6A to 6D, since carbons are introduced into the film of nickel constituting the carbon-containing catalyst metal film 26 to form the carbon-containing catalyst metal film 26, it is possible to suppress a fluctuation in introduction amount of the carbons into the carbon-containing catalyst metal film 26. Thus, it is possible to evenly diffuse the carbons into the carbon-containing catalyst metal film 26. As a result, it is possible to evenly diffuse the carbons in the graphene precipitation layer 31 formed from the carbon-containing catalyst metal film 26.

Although in the aforementioned graphene production method of FIGS. 6A to 6D, both the carbon-containing catalyst metal film 26 and the high crystalline base film 30 has been described to be composed of nickel, the high crystalline base film 30 may be composed of other metals exhibiting high orientation with respect to nickel. Even in this case, crystallinity of the high crystalline base film 30 can be imparted to the carbon-containing catalyst metal film 26.

Next, a third embodiment of the present disclosure will be described.

This embodiment is essentially identical in configuration and operation with the first embodiment described above, and a duplicate description thereof will be omitted. Only the differing configurations and operations will be described below.

In this embodiment, the processing chamber (adjustment film formation chamber) 22d is to form a low carbon concentration film (carbon concentration adjustment film) 3 differing from the carbon-containing catalyst metal film 26 in a carbon concentration.

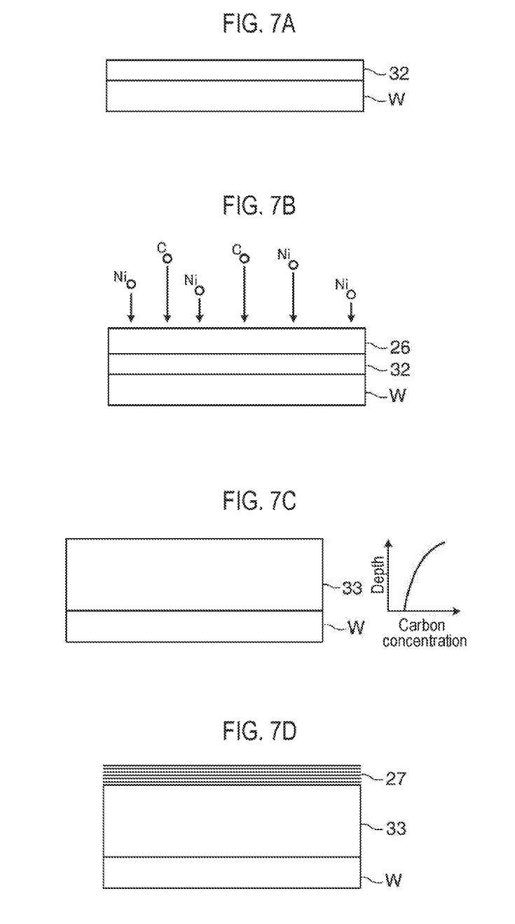

FIGS. 7A to 7D are process views explaining a graphene production method according to the third embodiment of the present disclosure.

First, in the processing chamber 22d, the low carbon concentration film 32 is formed on a surface of the water W (FIG. 7A). In this embodiment, the carbon concentration of the low carbon concentration film 32 is set to be lower than that of the carbon-containing catalyst film 26. The low carbon concentration film 32 is composed of a metal or a metal compound in which carbons are hard to dissolve, for example, alumina (Al₂O₃) or gold (Au). Specifically, the low carbon concentration film 32 is formed by PVD using alumina or gold as a target.

Subsequently, in the processing chamber 22a, the carbon-containing catalyst metal film 26 is formed to be brought into contact with the low carbon concentration film 32 by, for example, a PVD (FIG. 7B) using nickel and carbon as targets, a PVD using a nickel carbide as a target, a PVD using nickel as a target under a hydrocarbon gas atmosphere, or a CVD or ALD using gas of an organic nickel compound.

Thereafter, in the processing chamber 22b, the low carbon concentration film 32 and the carbon-containing catalyst metal film 26 are dissolved with respect to each other by heating to form a graphene precipitation layer 33 (FIG. 7C). At this time, since carbons contained in the carbon-containing catalyst metal film 26 is diffused toward the low carbon concentration film 32, a concentration of the carbons is changed in the graphene precipitation layer 33 in the thickness direction thereof. In other words, a gradient of the carbon concentration in the thickness direction is increased. Specifically, the carbon concentration is lowered at a portion at which the carbon-containing catalyst metal film 26 and the low carbon concentration film 32 are brought into contact with each other, but is relatively increased in the vicinity of the surface of the carbon-containing catalyst metal film 26, that is to say, in the vicinity of a surface (an upper surface in FIG. 7C) of the graphene precipitation layer 33 (see a graph in FIG. 7C).

Next, in the processing chamber 22b, the graphene precipitation layer 33 is cooled down. At this time, since solubility of the carbons in the graphene precipitation layer 33 is lowered, saturated carbons are crystalized in the surface of the graphene precipitation layer 33 to precipitate the graphene 27 (FIG. 7D). In general, since a precipitation location of graphene is significantly affected by the gradient of a carbon concentration in a catalyst metal film, the graphene is precipitated starting from a location at which the carbon concentration is high. Accordingly, in this embodiment, the graphene 27 is precipitated from the surface of the graphene precipitation layer 33.

According to the graphene production method of FIGS. 7A to 7D, since the carbon-containing catalyst metal film 26 differing from the carbon-containing catalyst metal film 26 in a carbon concentration is formed to be brought into contact with the low carbon concentration film 32, it is possible to arbitrarily control the gradient of the carbon concentration in the graphene precipitation layer 33, which is formed from the low carbon concentration film 32 and the carbon-containing catalyst metal film 26, in a thickness direction of the graphene precipitation layer 33. It is therefore possible to control the precipitation location of the graphene 27. Specifically, it is possible to increase the carbon concentration in the vicinity of the surface of the graphene precipitation layer 33, thus precipitating the graphene from the surface of the graphene precipitation layer 33.

Furthermore, in the graphene production method of FIGS. 7A to 7D, since the carbons are introduced into the film of nickel constituting the carbon-containing catalyst metal film 26 to form the carbon-containing catalyst metal film 26, it is possible to suppress a fluctuation in the introduction amount of the carbons into the carbon-containing catalyst metal film 26. Thus, it is possible to evenly diffuse the carbons in the carbon-containing catalyst metal film 26. As a result, it is possible to evenly diffuse the carbons in the graphene precipitation layer 33 formed from the carbon-containing catalyst metal film 26 even in a direction (i.e., horizontal direction) perpendicular to the thickness direction. This makes it possible to evenly precipitate a graphene 27 in the surface of the graphene precipitation layer 33, thus producing the graphene 27 with high quality.

Although in the aforementioned graphene production method of FIGS. 7A to 7D, the graphene 27 has been described to be precipitated from the surface of the graphene precipitation layer 33, the 27 may be precipitated from an interface between the wafer W and the graphene precipitation layer 33, that is to say, from a rear surface of the graphene precipitation layer 33, by changing a formation sequence of the low carbon concentration film 32 and the carbon-containing catalyst metal film 26.

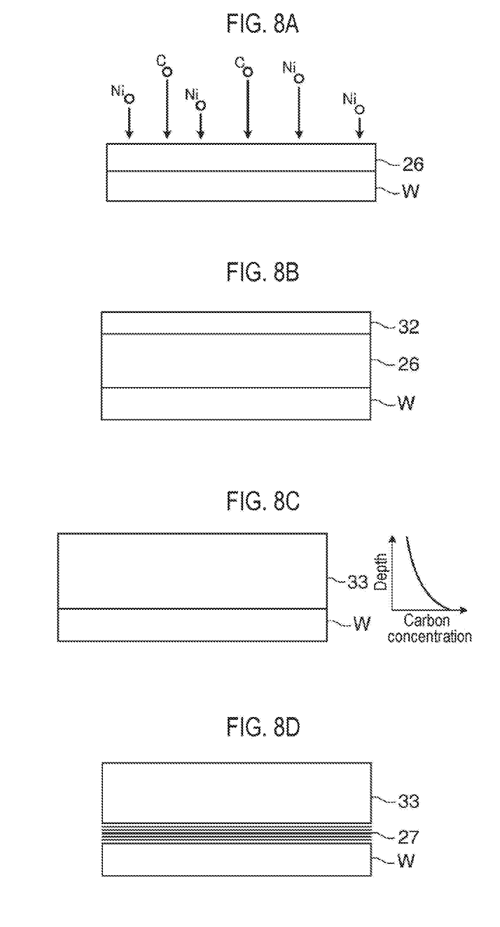

FIGS. 8A to 8D are process views showing a first modification of the graphene production method according to the third embodiment of the present disclosure.

First, in the processing chamber 22a, a carbon-containing catalyst metal film 26 is formed on a surface of the wafer W, by, for example, a PVD (FIG. 8B) using nickel and carbon as targets, a PVD using a nickel carbide as a target, a PVD using nickel as a target under a hydrocarbon gas atmosphere, or a CVD or AHD using gas of an organic nickel compound.

Subsequently, in the processing chamber 22d, a low carbon concentration film 32 is formed to be brought into contact with the carbon-containing catalyst metal film 26 (FIG. 8B). Even in this modification, a concentration of carbons in the low carbon concentration film 32 is set to be lower than that in the carbon-containing catalyst metal film 26, and the low carbon concentration film 32 is composed of alumina or gold.

Thereafter, in the processing chamber 22b, the low carbon concentration film 32 and the carbon-containing catalyst metal film 26 are dissolved with respect to each other by heating to form a graphene precipitation layer 33 (FIG. 8C). At this time, since carbons contained in the carbon-containing catalyst metal film 26 are diffused toward the low carbon concentration film 32, a concentration of the carbons at a portion where the carbon-containing catalyst metal film 26 is brought into contact with the low carbon concentration film 32 in the graphene precipitation layer 33 is lowered, while the concentration of the carbons in the vicinity of an interface between the carbon-containing catalyst metal film 26 and the wafer W, that is to say, in the vicinity of a rear surface (a lower surface in the drawing) of the graphene precipitation layer 33 is relatively increased (see a graph in FIG. 8C).

Subsequently, in the processing chamber 22b, the graphene precipitation layer 33 is cooled down. As described above, since the carbon concentration in the vicinity of the rear surface of the graphene precipitation layer 33 is high, saturated carbons are crystallized in the interface between the graphene precipitation layer 33 and the wafer W to precipitate a graphene 27 (FIG. 8D). That is to say, it is possible to precipitate the graphene 27 from the rear surface of the graphene precipitation layer 33.

Although in the aforementioned graphene production methods of FIGS. 7A to 7D and FIGS. 8A to 8D, the low carbon concentration film 32 having the carbon concentration lower than the carbon-containing catalyst metal film 26 has been described to be used, a carbon concentration adjustment film having a carbon concentration higher than that of the carbon-containing catalyst metal film 26 may be used to control a gradient of the carbon concentration in the graphene precipitation layer 33.

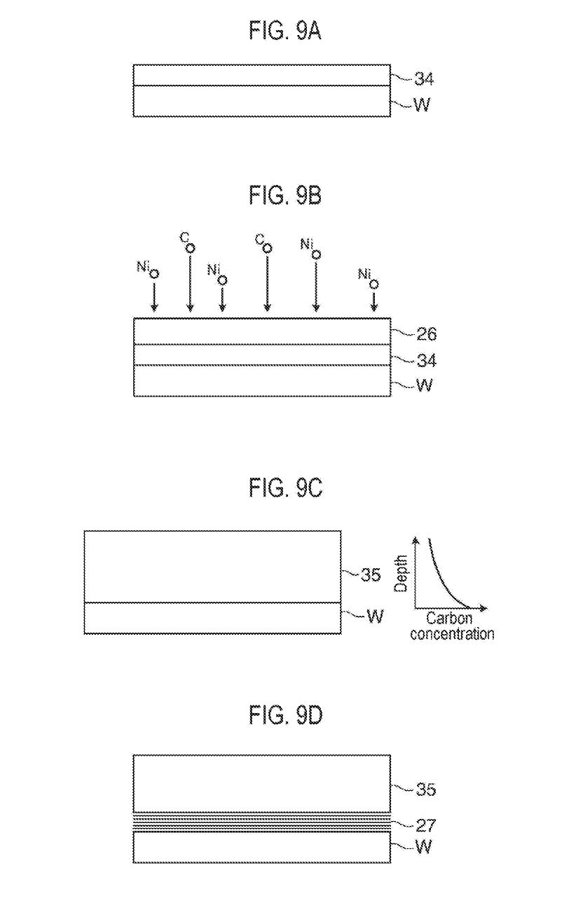

FIGS. 9A to 9D are process views showing a second modification of the graphene production method according to the third embodiment of the present disclosure.

First, in the processing chamber 22d, a high carbon concentration layer carbon concentration adjustment film) 34 is formed on a surface of the wafer (FIG. 9A). In this modification, a carbon concentration of the high carbon concentration layer 34 is set to be higher than that of the carbon-containing catalyst metal film 26.

The high carbon concentration layer 34 is composed of a nickel carbide, a mixture of nickel and carbon, an organic nickel compound, or a solid carbon source (for example, a carbon layer composed of an amorphous carbon or an organic polymer film). In a case where the high carbon concentration layer 34 is composed of the nickel carbide, the mixture of nickel and carbon, or the organic nickel compound, for example, a PAID using nickel and carbon as targets, a PVD using the nickel carbide as a target, a PVD using nickel as a target under a hydrocarbon gas atmosphere, or a CVD o ALD using gas of the organic nickel compound, is used as a method of forming the high carbon concentration layer 34. Further, in a case where the high carbon concentration layer 34 is composed of the solid carbon source, a PVD using carbon as a target, a microwave CVD under a hydrocarbon gas atmosphere or coating of an organic polymer material is used as the method of forming the high carbon concentration layer 34. In some embodiments, the high carbon concentration layer 34 may be composed of cobalt, iron, titanium, rhodium, palladium, platinum, or mixtures of these materials, instead of nickel.

Subsequently, in the processing chamber 22a, the carbon-containing catalyst metal film 26 is formed to be brought into contact with the high carbon concentration layer 34 by, for example, the PVD using nickel and carbon as targets (FIG. 9B).

Thereafter, in the processing chamber 22b, the high carbon concentration layer 34 and the carbon-containing catalyst metal film 26 are dissolved with respect to each other by heating to form a graphene precipitation layer 35 (FIG. 9C). At this time, since carbons contained in the high carbon concentration layer 34 is diffused toward the carbon-containing catalyst metal film 26 in the graphene precipitation layer 35, a carbon concentration at a portion where the carbon-containing catalyst metal film 26 is brought into contact with the high carbon concentration layer 34 is increased, while the carbon concentration in the vicinity of a surface of the carbon-containing catalyst metal film 26, that is to say, in the vicinity of a surface (an upper surface in the drawing) of the graphene precipitation layer 35, is relatively decreased. On the other hand, a carbon concentration in the vicinity of a rear surface (a lower surface in the drawing) of the graphene precipitation layer 35 is increased (see a graph in FIG. 9C).

Subsequently, in the processing chamber 22b, the graphene precipitation layer 35 is cooled down. As described above, since the carbon concentration in the vicinity of the rear surface of the graphene precipitation layer 35 is high, it is possible to precipitate a graphene 27 from the rear surface of the graphene precipitation layer 35 (FIG. 9D).

Although in the aforementioned graphene production methods of FIGS. 7A to 7D to FIGS. 9A to 9D, the low carbon concentration 32 or the high carbon concentration layer 34 has been described to be formed in a single layer, each of these films may be formed in plural layers having different carbon concentrations. With this configuration, it is possible to more precisely control a gradient of the carbon concentration in each of the graphene precipitation layers 31, 33 and 35 in a thickness direction.

Although in the aforementioned graphene production methods of FIGS. 7A to 7D to FIGS. 9A to 9D, each of the graphene precipitation layers 31, 33 and 35 has been described to be formed to have the carbon concentration gradient in the thickness direction by dissolving carbons contained in the low carbon concentration film 32 or the high carbon concentration layer 34 into the carbon-containing catalyst metal film 26, the present disclosure is not limited thereto. In some embodiments, the carbon concentration gradient of the carbon-containing catalyst metal film 26 in the thickness direction may be controlled by, for example, changing a concentration of carbons to be introduced into a nickel film over time when forming the carbon-containing catalyst metal film 26, without having to use the low carbon concentration film 32 or the high carbon concentration layer 34. Alternatively, the graphene precipitation layers 31, 33 and 35 may be formed by allowing the carbon-containing catalyst metal film 26 whose carbon concentration gradient in the thickness direction is controlled, and the low carbon concentration film 32 or the high carbon concentration layer 34 to be dissolved with respect to each other.

Although the present disclosure has been described with reference to some embodiments, the present disclosure is not limited thereto.

As an example, the graphene production methods according to the second and third embodiments may be combined. Specifically, both the high crystalline base film 30 and the low carbon concentration film 32 may be formed on the surface of the wafer W.

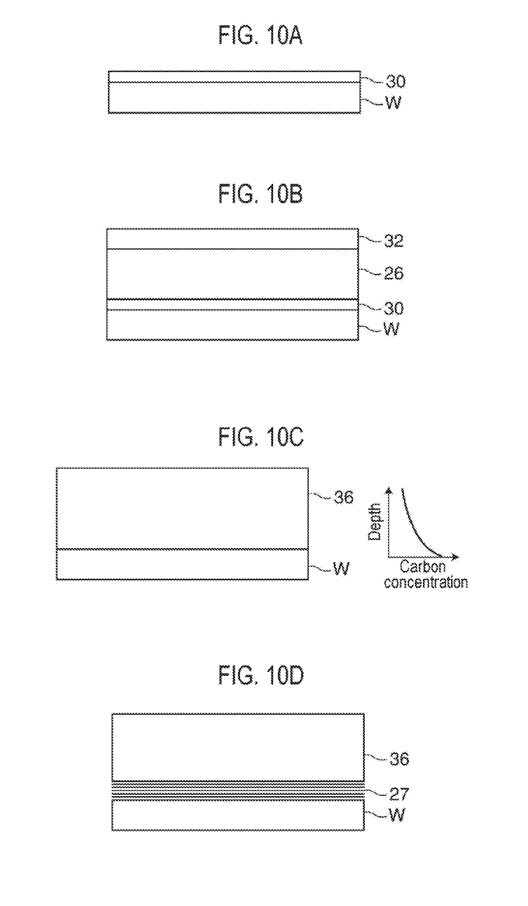

FIGS. 10A to 10D are process views showing a modification in which the graphene production methods according to the second and third embodiments of the present disclosure are combined.

First, in the processing chamber 22c, a high crystalline base film 30 is formed on a surface of the wafer W (FIG. 10A).

Subsequently, in the processing chamber 22a, a carbon-containing catalyst metal film 26 is formed to be brought into contact with the high crystalline base film 30. At this time, crystallinity of the high crystalline base film 30 is imparted to the carbon-containing catalyst metal film 26 such that the carbon-containing catalyst metal film 26 has high crystallinity. Further, in the processing chamber 22d, a low carbon concentration film 32 is formed to be brought into contact with the carbon-containing catalyst metal film 26 (FIG. 10B).

Thereafter, in the processing chamber 221), the high crystalline base film 30, the low carbon concentration film 32 and the carbon-containing catalyst metal film 26 are dissolved with respect to each other by heating to form a graphene precipitation layer 36 (FIG. 10C). At this time, since both the high crystalline base film 30 and the carbon-containing catalyst metal film 26 have high crystallinity, the graphene precipitation layer 36 also has high crystallinity. Furthermore, since carbons contained in the carbon-containing catalyst metal film 26 are diffused into the low carbon concentration film 32, a carbon concentration at a portion where the carbon-containing catalyst metal film 26 is brought into contact with the low carbon concentration film 32 in the graphene precipitation layer 36 is decreased, while a carbon concentration in the vicinity of a rear surface (a lower surface in the drawing) of the graphene precipitation layer 36 is relatively increased (see a graph in FIG. 10C).

Subsequently, in the processing chamber 22b, the graphene precipitation layer 36 is cooled down. As described above, since the carbon concentration in the vicinity of the rear surface of the graphene precipitation layer 36 is high, it is possible to precipitate a graphene 27 from the rear surface of the graphene precipitation layer 36 (FIG. 10D). In addition, since the graphene precipitation layer 36 has high crystallinity, it is possible to produce the graphene 27 having high crystallinity.

Although in each of the above embodiments, the graphene production system 17 provided with the plurality of processing chambers 22a to 22d has been described to be used in producing the graphene 27, the present disclosure is not limited thereto, As an example, in a case where a single processing chamber is configured to form the carbon-containing catalyst metal film 26, the high crystalline base film 30, the low carbon concentration film 32 or the high carbon concentration layer 34, and configured to precipitate the graphene 27, each of the graphene production methods according to the above embodiments may be carried out using a graphene production apparatus provided with such a single processing chamber, instead of the graphene production system 17.

Moreover, the objective of the present disclosure may be achieved by providing a memory medium that stores a program code of a software for implementing respective functions of the above embodiments to the control part 24 installed in the graphene production system 17, and by allowing a central processing unit of the control part 24 to read and execute the program code stored in the memory medium.

In such a case, the program code itself which read from the memory medium implements the respective functions of the above embodiments, and the program code and the memory medium that stores the program code constitute the present disclosure.

In addition, examples of the memory medium for providing the program code may include RAM, NV-RAM, a floppy (registered mark) disk, a hard disk, an optomagnetic disk, an optical disk such as CD-ROM, CD-R, CD-RW and DVD (DVD-ROM, DVD-RAM, DVD-RW, DVD+RW), a magnetic tape, a nonvolatile memory card, and other ROMs, which are capable of storing the program code. Alternatively, the program code may be provided to the control part 24 by downloading from another computer and data base (both not shown) which are connected to an internet, a commercial network, a local area network or the like.

Further, the respective functions of the above embodiments may be implemented by executing the program code which is read by the control part 24, and by allowing an OS (operating system) running on the CPU to execute a portion or all of the actual processes based on an instruction of the program code.

Further, the respective functions of the above embodiments may be implemented by writing the program code read from the memory medium into a memory provided in a function expansion board inserted into the control part 24 or a function expansion unit connected to the control part 24, and by allowing a CPU or the like provided in the function expansion board or the function expansion unit to execute a portion or all of the actual processes based on an instruction of the program code.

The program code may be configured in a form such as an object code, a program code executed by an interpreter, a script data provided to the OS, or the like.

According to the present disclosure in some embodiments, carbons are introduced into a catalyst metal film when forming the catalyst metal film. In other words, since the formation of the catalyst metal film and the introduction of the carbons into the catalyst metal film are simultaneously performed, there is no need to dissolve carbons in a carbon-containing gas into the catalyst metal film. Thus, it is possible to suppress a fluctuation in introduction amount of the carbons into the catalyst metal film, thereby evenly diffusing the carbons in the catalyst metal film. It is therefore possible to produce high quality graphene.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A graphene production method comprising:
forming a catalyst metal film on a surface of a substrate;
heating the catalyst metal film; and
cooling the heated catalyst metal film,
wherein the forming a catalyst metal film includes introducing carbons into the catalyst metal film.

2. The graphene production method of claim 1, wherein the catalyst metal film is composed of a metal carbide or an organic metal compound.

3. The graphene production method of claim 1, wherein the catalyst metal film is formed by a chemical vapor deposition (CVD), a physical vapor deposition (PVD) or an atomic layer deposition (ALD).

4. The graphene production method of claim 1, wherein the heating the catalyst layer includes supplying a carbon-containing gas toward the catalyst metal film.

5. The graphene production method of claim 1, further comprising: before forming a catalyst metal film, forming a high crystalline base film,
wherein the forming a catalyst metal film forms the catalyst metal film to be brought into contact with the high crystalline base film.

6. The graphene production method of claim 1, further comprising:
forming a carbon concentration adjustment film having a carbon concentration different from that of the catalyst metal film,
wherein the forming a catalyst metal film forms the catalyst metal film to be brought into contact with the carbon concentration adjustment film.

7. The graphene production method of claim 6, wherein the forming a carbon concentration adjustment film is performed prior to the forming a catalyst metal film such that the carbon concentration adjustment film is formed between the substrate and the catalyst metal film.

8. The graphene production method of claim 6, wherein the forming a catalyst metal film is performed prior to the forming a carbon concentration adjustment film such that the catalyst metal film is formed between the substrate and the carbon concentration adjustment film.

9. The graphene production method of claim 6, wherein a carbon concentration of the catalyst metal film is higher than the carbon concentration of the carbon concentration adjustment film.

10. The graphene production method of claim 6, wherein a carbon concentration of the catalyst metal film is lower than the carbon concentration of the carbon concentration adjustment film.

11. The graphene production method of claim 6, wherein the forming a carbon concentration adjustment film includes forming a plurality of carbon concentration adjustment films having different carbon concentrations.

12. A graphene production apparatus which forms a catalyst metal film on a surface of a substrate, heats the catalyst metal film, and cools down the heated catalyst metal film, wherein when forming the catalyst metal film, carbons are introduced into the catalyst metal film.

13. A graphene production system provided with a plurality of processing chambers,
wherein at least two of the plurality of processing chambers are configured as a metal film formation chamber for forming a catalyst metal film on a surface of a substrate and a graphene precipitation chamber for precipitating graphene in a surface of the catalyst metal film,
wherein the metal film formation chamber is configured to allow carbons to be introduced into the catalyst metal film, when forming the catalyst metal film,
wherein the graphene precipitation chamber is configured to heat the formed catalyst metal film and to cool down the heated catalyst metal film.

14. The graphene production system of claim 13, wherein one of the plurality of processing chambers is configured as abase film formation chamber for forming a high crystalline base film prior to the forming a catalyst metal film, and the metal film formation chamber forms the catalyst metal film to be brought into contact with the high crystalline base film.

15. The graphene production system of claim 13, wherein one of the plurality of processing chambers is configured as an adjustment film formation chamber for forming a carbon concentration adjustment film having a carbon concentration different from that of the catalyst metal film, and the metal film formation chamber forms the catalyst metal film to be brought into contact with the carbon concentration adjustment film.
